(19) United States
(12) Patent Application Publication
(10) Pub. No.: US 2025/0028236 A1
(43) Pub. Date: Jan. 23, 2025

(54) HARDMASK COMPOSITION, HARDMASK LAYER, AND METHOD OF FORMING PATTERNS

(71) Applicant: SAMSUNG SDI CO., LTD., Yongin-si (KR)

(72) Inventors: Younhee NAM, Suwon-si (KR); Yushin PARK, Suwon-si (KR); Seunghyun KIM, Suwon-si (KR); Seulgi JEONG, Suwon-si (KR); Sangchol PARK, Suwon-si (KR); Minji SO, Suwon-si (KR); Jooyoung CHUNG, Suwon-si (KR)

(21) Appl. No.: 18/678,090

(22) Filed: May 30, 2024

(30) Foreign Application Priority Data
Jul. 13, 2023 (KR) 10-2023-0091250

(51) Int. Cl. G03F 1/50

(52) U.S. Cl. CPC G03F 1/50

(57) ABSTRACT

A hardmask composition, a hardmask layer manufactured from the hardmask composition, and a method of forming a pattern or patterns using the hardmask layer manufactured from the hardmask composition, the hardmask composition includes a polymer including a structural unit represented by Chemical Formula 1; and a solvent,

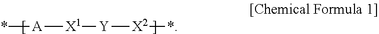

### CROSS-REFERENCE TO RELATED APPLICATION

This application claims priority to and the benefit of Korean Patent Application No. 10-2023-0091250 filed in the Korean Intellectual Property Office on Jul. 13, 2023, the entire contents of which are incorporated herein by reference.

### BACKGROUND

### 1. Field

Embodiments relate to a hardmask composition, a hardmask layer, and a method of forming patterns.

### 2. Description of the Related Art

Recently, the semiconductor industry has developed to an ultra-fine technique having a pattern of several to several tens nanometer size. Such ultrafine technique may utilize effective lithographic techniques. Some lithographic techniques may include providing a material layer on a semiconductor substrate; coating a photoresist layer thereon; exposing and developing the same to provide a photoresist pattern; and etching a material layer using the photoresist pattern as a mask. Nowadays, according to small-sizing the pattern to be formed, it may be difficult to provide a fine pattern having an excellent profile by only using some lithographic techniques. Accordingly, an auxiliary layer, called a hardmask layer, may be formed between the material layer and the photoresist layer to provide a fine pattern.

### SUMMARY

The embodiments may be realized by providing a hardmask composition including a polymer including a structural unit represented by Chemical Formula 1; and a solvent:

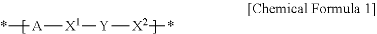

wherein, in Chemical Formula 1, A is a substituted or unsubstituted C6 to C30 aromatic hydrocarbon group, X¹ and X² are each independently a single bond, —C(═O)—, a substituted or unsubstituted C1 to C30 alkylene group, or a combination thereof, Y is a substituted or unsubstituted C2 to C30 alkenylene group or a substituted or unsubstituted C2 to C30 alkynylene group, and * is a linking point.

A may be a substituted or unsubstituted C6 to C30 aromatic hydrocarbon group of a moiety of Group 1:

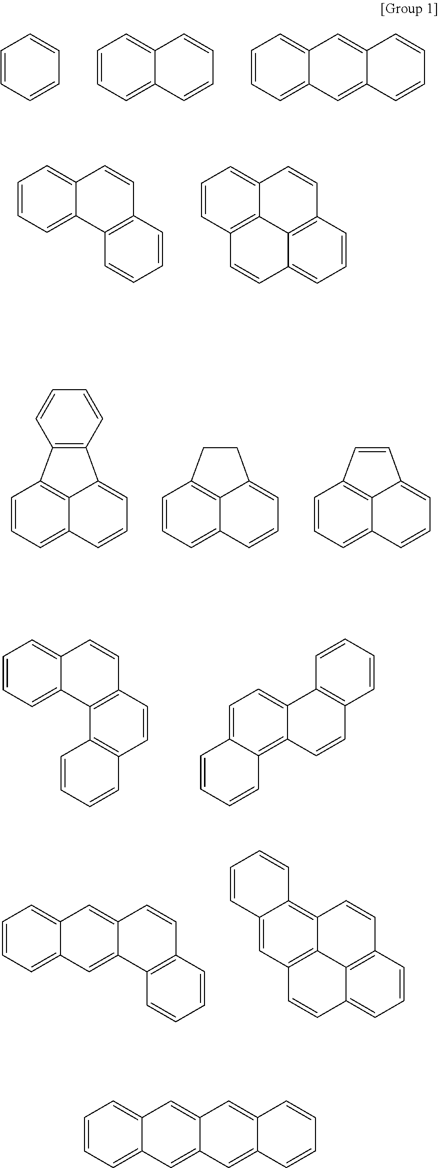

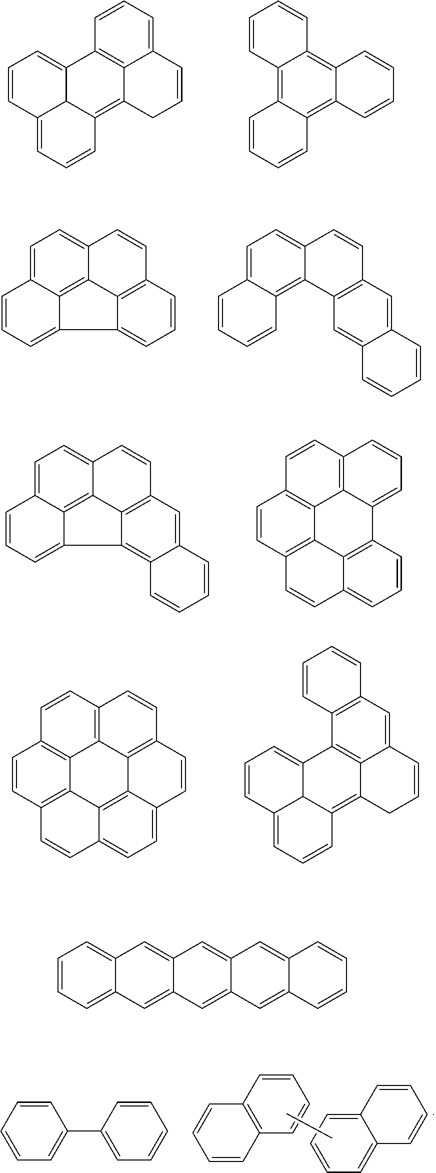

A may be a substituted C6 to C30 aromatic hydrocarbon group, and a substituent of the substituted C6 to C30 aromatic hydrocarbon group may be deuterium, a hydroxy group, a halogen atom, a C1 to C20 alkyl group, a C2 to C20 alkenyl group, a C2 to C20 alkynyl group, a C1 to C20 heteroalkyl group, a C6 to C20 aryl group, a C3 to C20 heteroaryl group, or a combination thereof.

X¹ and X² may each independently be —C(═O)—, a substituted C1 to C20 alkylene group, or a combination thereof.

Y may be a substituted or unsubstituted C2 to C10 alkenylene group or a substituted or unsubstituted C2 to C10 alkynylene group.

A may be a substituted or unsubstituted C6 to C30 aromatic hydrocarbon group of a moiety of Group 1-1:

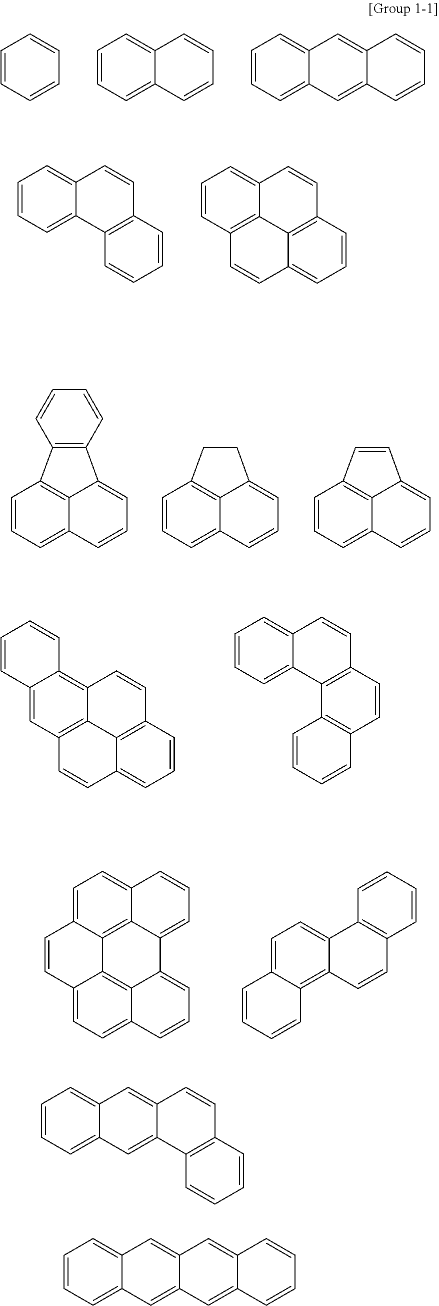

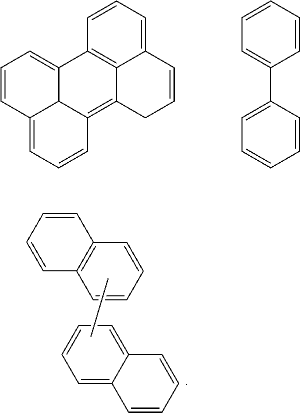

Chemical Formula 1 may be represented by Chemical Formula 1-1 or Chemical Formula 1-2:

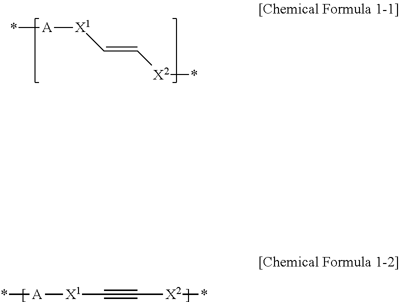

in Chemical Formula 1-1 and Chemical Formula 1-2, A may be a substituted or unsubstituted C6 to C30 aromatic hydrocarbon group of a moiety of Group 1-1, X¹ and X² may each independently be a single bond, —C(═O)—, a substituted or unsubstituted C1 to C30 alkylene group, or a combination thereof, and * is a linking point:

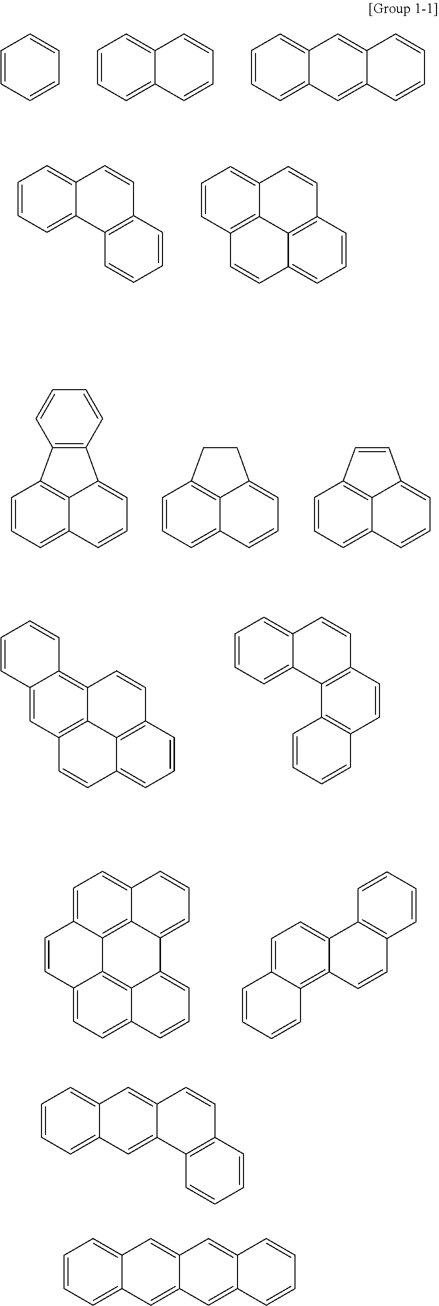

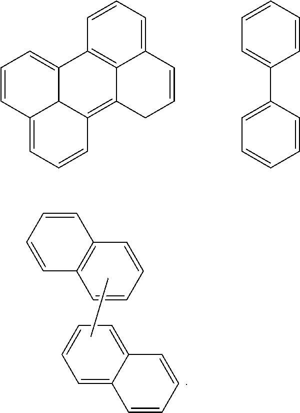

Chemical Formula 1 may be represented by one of Chemical Formula 1-1-1 to Chemical Formula 1-1-4 and Chemical Formula 1-2-1 to Chemical Formula 1-2-4:

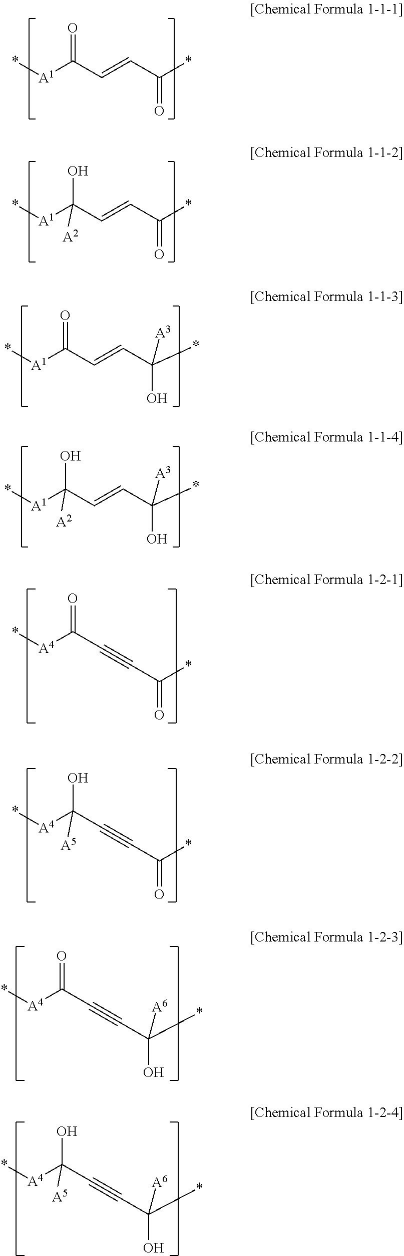

in Chemical Formula 1-1-1 to Chemical Formula 1-1-4 and Chemical Formula 1-2-1 to Chemical Formula 1-2-4, A1 to A6 may each independently be a substituted or unsubstituted C6 to C30 aromatic hydrocarbon group.

A1 to A6 may are each independently be a substituted or unsubstituted C6 to C30 aromatic hydrocarbon group of a moiety of Group 1-1:

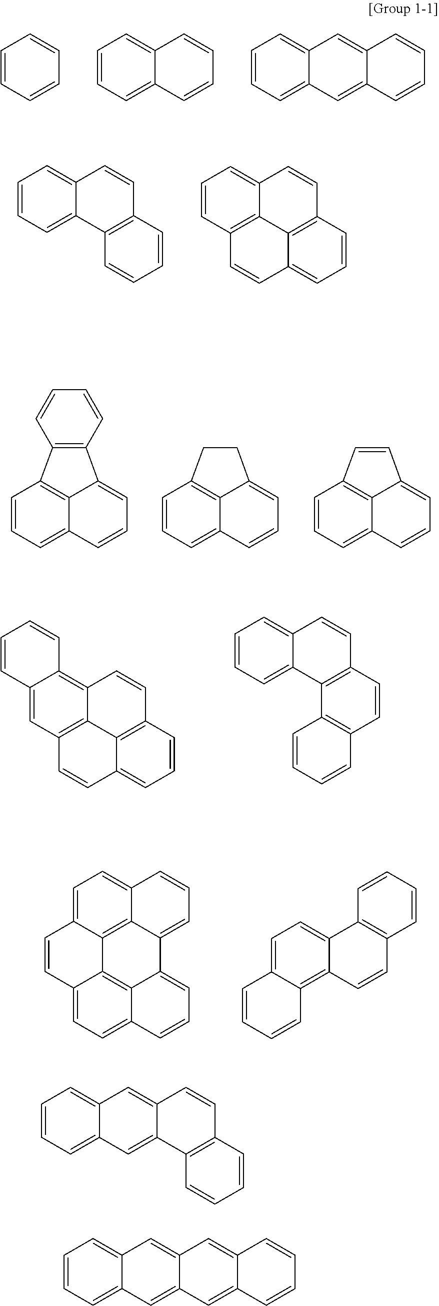

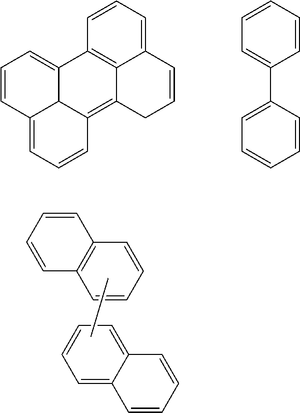

The polymer may further include a structural unit represented by Chemical Formula 2,

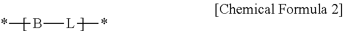

in Chemical Formula 2, B may be a substituted or unsubstituted C6 to C30 aromatic hydrocarbon group, L may be a single bond or a substituted or unsubstituted C1 to C30 alkylene group, and * is a linking point.

B in Chemical Formula 2 may be a substituted or unsubstituted C6 to C30 aromatic hydrocarbon group of a moiety of Group 2:

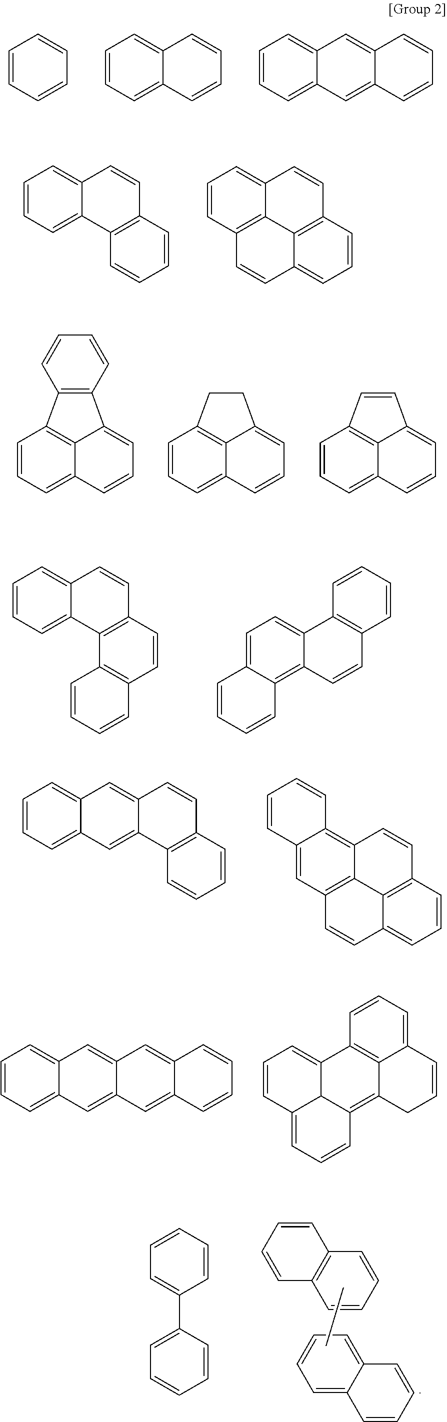

L in Chemical Formula 2 may be a substituted or unsubstituted methylene group.

The polymer may have a weight average molecular weight of about 1,000 g/mol to about 200,000 g/mol.

The polymer may be included in an amount of about 0.1 wt % to about 30 wt %, based on a total weight of the hardmask composition.

The solvent may include propylene glycol, propylene glycol diacetate, methoxy propanediol, diethylene glycol, diethylene glycol butylether, tri (ethylene glycol) monomethylether, propylene glycol monomethylether, propylene glycol monomethylether acetate, cyclohexanone, ethyl lactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer including a cured product of the hardmask composition according to an embodiment.

The embodiments may be realized by providing a method of forming patterns, the method including providing a material layer on a substrate; applying the hardmask composition according to an embodiment to the material layer; heat-treating the hardmask composition to form a hardmask layer; forming a photoresist layer on the hardmask layer, exposing and developing the photoresist layer to form a photoresist pattern; selectively removing the hardmask layer using the photoresist pattern to expose a portion of the material layer; and etching an exposed part of the material layer.

Forming the hardmask layer may include heat-treating at about 100° C. to about 1,000° C.

### DETAILED DESCRIPTION

Example embodiments will now be described more fully hereinafter; however, they may be embodied in different forms and should not be construed as limited to the embodiments set forth herein. Rather, these embodiments are provided so that this disclosure will be thorough and complete, and will fully convey exemplary implementations to those skilled in the art.

It will also be understood that when a layer or element is referred to as being “on” another layer or element, it can be directly on the other layer or element, or intervening layers may also be present. In addition, it will also be understood that when a layer is referred to as being “between” two layers, it can be the only layer between the two layers, or one or more intervening layers may also be present.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (—H) may include deuterium substitution (—D) or tritium substitution (—T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B. As used herein, unless described otherwise, * is a linking point.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring. For example, the substituted C6 to C30 aryl group may be fused with another adjacent substituted C6 to C30 aryl group to form a substituted or unsubstituted fluorene ring.

As used herein, when a definition is not otherwise provided, “aromatic hydrocarbon group” means a group having one or more hydrocarbon aromatic moieties, and includes a form in which hydrocarbon aromatic moieties are linked by a single bond, a non-aromatic fused ring form in which hydrocarbon aromatic moieties are fused directly or indirectly, or a combination thereof as well as non-condensed aromatic hydrocarbon rings, condensed aromatic hydrocarbon rings.

More specifically, the substituted or unsubstituted aromatic hydrocarbon group may be a substituted or unsubstituted phenyl group (phenylene group), a substituted or unsubstituted naphthyl group (naphthylene group), a substituted or unsubstituted anthracenyl group (anthracenylene group), a substituted or unsubstituted phenanthryl group (phenanthrylene group), a substituted or unsubstituted naphthacenyl group (naphthacenylene group), a substituted or unsubstituted pyrenyl group (pyrenylene group), a substituted or unsubstituted biphenyl group (biphenylene group), a substituted or unsubstituted terphenyl group (terphenylene group), a substituted or unsubstituted quaterphenyl group (quaterphenylene group), a substituted or unsubstituted chrysenyl group (chrysenylene group), a substituted or unsubstituted triphenylenyl group (triphenylenylene group), a substituted or unsubstituted perylenyl group (perylenylene group), a substituted or unsubstituted indenyl group (indenylene group), a combination thereof, or a combined fused ring of the foregoing groups, but is not limited thereto.

As used herein, when a definition is not otherwise provided, “hetero” refers to one including one to 3 heteroatoms selected from N, O, S, Se, and P.

As used herein, when a definition is not otherwise provided, “heteroalkyl group” refers to a group including a hetero element selected from N, O, S, P and Si instead of one or more carbon atoms forming an alkyl group.

As used herein, when a definition is not otherwise provided, “heteroaryl group” refers to an aryl group including at least one heteroatom selected from N, O, S, P, and Si. Two or more heteroaryl groups may be directly linked through a sigma bond, or when the heteroaryl group includes two or more rings, the two or more rings may be fused to each other. When the heteroaryl group is a fused ring, each ring may contain 1 to 3 heteroatoms.

As used herein, the polymer may include both an oligomer and a polymer.

Unless otherwise specified in the present specification, the “weight average molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

The hardmask composition according to some embodiments may include, e.g., a polymer including a structural unit represented by Chemical Formula 1, and a solvent.

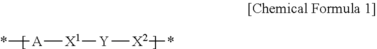

In Chemical Formula 1, A may be or may include, e.g., a substituted or unsubstituted C6 to C30 aromatic hydrocarbon group.

X¹ and X² may each independently be or include, e.g., a single bond, —C(═O)—, a substituted or unsubstituted C1 to C30 alkylene group, or a combination thereof.

Y may be or may include, e.g., a substituted or unsubstituted C2 to C30 alkenylene group or a substituted or unsubstituted C2 to C30 alkynylene group.

* is a linking point.

The polymer included in the hardmask composition according to some embodiments may include an aromatic hydrocarbon group. Accordingly, the carbon content in the polymer including the structural unit may increase, and a hardmask layer formed from a hardmask composition including the polymer may have high etch resistance.

In addition, the structural unit represented by Chemical Formula 1 may include an unsaturated hydrocarbon, so that a number of crosslinks due to a cycloaddition reaction may increase during curing of the hardmask composition, thereby ensuring etch resistance and heat resistance. The composition may not form a ring in the pre-cured state, and it may have excellent solubility properties and excellent flattening properties and gap-fill characteristics when applied using a spin-coating method.

In addition, by including unsaturated hydrocarbons in the main chain of the polymer, a loss of unsaturated hydrocarbons may be reduced during heat-treating process and under curing conditions of the hardmask composition, thereby increasing the number of crosslinks in the polymer compared to the case where unsaturated hydrocarbons are included in the side chains or terminal ends of the polymer and thus improving crosslinking characteristics of the hardmask composition and securing excellent film strength of the hardmask layer formed therefrom.

In an implementation, A may be, e.g., a substituted or unsubstituted C6 to C30 aromatic hydrocarbon group of a moiety of Group 1. As used herein, the substituted or unsubstituted aromatic hydrocarbon group of a moiety refers to a (e.g., divalent) group of one of the moieties that is unsubstituted, as illustrated, or the group may be further substituted as described above.

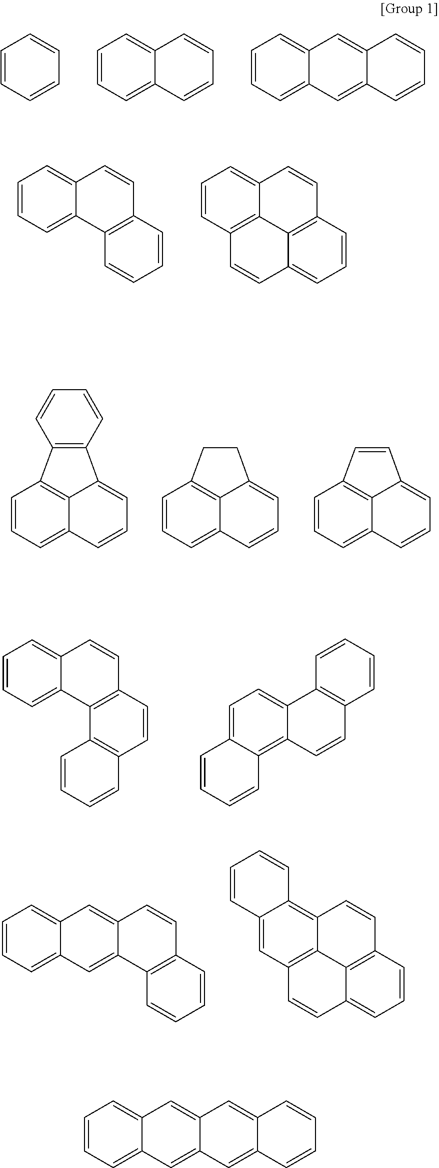

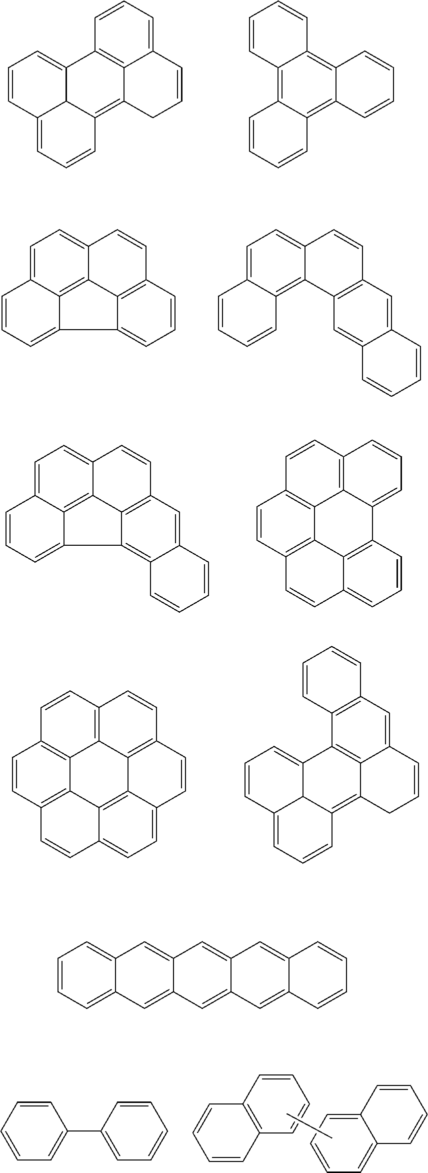

In an implementation, A may be, e.g., a substituted aromatic hydrocarbon group of a moiety of Group 1, and may be substituted with deuterium, a hydroxy group, a halogen atom, a C1 to C20 alkyl group, a C2 to C20 alkenyl group, a C2 to C20 alkynyl group, a C1 to C20 heteroalkyl group, a C6 to C20 aryl group, a C3 to C20 heteroaryl group, or a combination thereof.

In an implementation, A may be, e.g., a substituted or unsubstituted aromatic hydrocarbon group of a moiety of Group 1-1. In an implementation, A may be, e.g., a substituted or unsubstituted biphenylene, pyrene, naphthalene, benzoperylene, or the like.

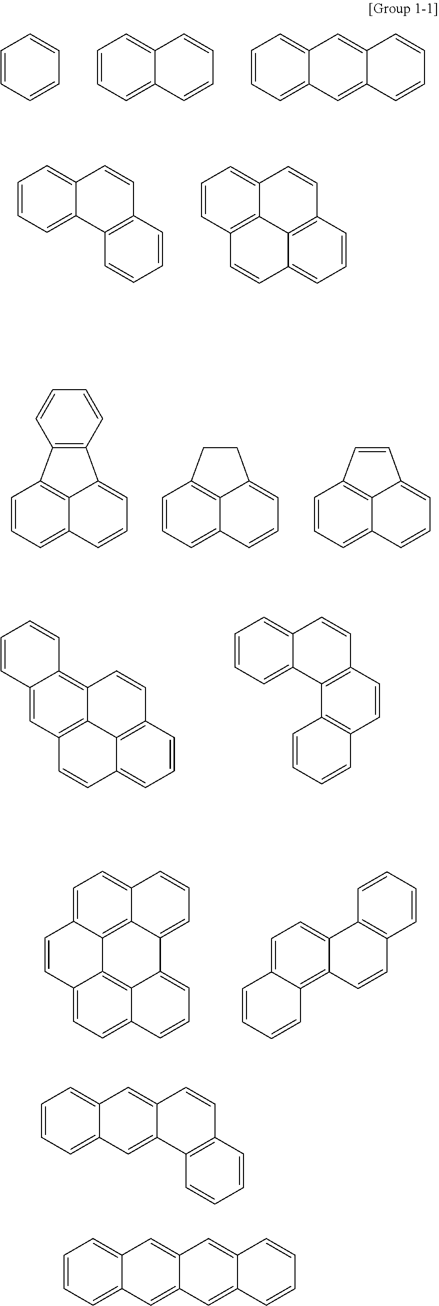

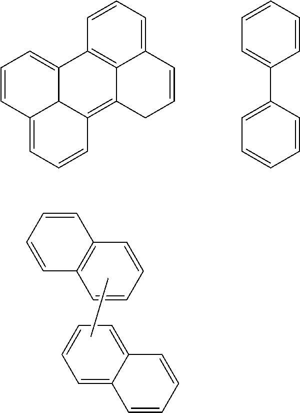

In an implementation, X¹ and X² may each independently be, e.g., —C(═O)—, a substituted C1 to C20 alkylene group, or a combination thereof. In an implementation, the substituted C1 to C20 alkylene group may be, e.g., a methylene group, an ethylene group, a propylene group, a butylene group, a pentylene group, a hexylene group, a heptylene group, an octylene group, or the like, in which a hydrogen is substituted with a substituent, e.g., a substituted methylene group, ethylene group, or propylene group.

The substituents of the substituted C1 to C20 alkylene group may include, e.g., a halogen atom (F, Br, Cl, or I), a hydroxy group, an alkoxy group, a cyano group, an azido group, a carbonyl group, a thiol group, an ester group, a vinyl group, a C1 to C20 alkyl group, a C2 to C20 alkenyl group, a C2 to C20 alkynyl group, a C1 to C20 heteroalkyl group, a C6 to C30 aryl group, a C3 to C20 heteroaryl group, or a combination thereof, e.g., a hydroxy group, an alkoxy group, a carbonyl group, or a C6 to C30 aryl group.

In an implementation, X¹ and X² may include —C(═O)— or a hydroxy group and/or a C6 to C30 aryl group as a substituent, when curing the hardmask composition, the crosslinking characteristics of the hardmask composition can be improved by increasing the number of crosslinks in the polymer, and the strength of the hardmask layer formed therefrom may be improved, thereby improving pattern-forming ability.

In an implementation, Y may be, e.g., a substituted or unsubstituted C2 to C10 alkenylene group or a substituted or unsubstituted C2 to C10 alkynylene group. The substituted or unsubstituted C2 to C10 alkenylene group may be, e.g., a C2 to C10, a C2 to C7, or a C2 to C5 alkenylene group, or an unsaturated aliphatic hydrocarbon group including at least one or more carbon double bond. The substituted or unsubstituted C2 to C10 alkynylene group may be, e.g., a C2 to C10, a C2 to C7, or a C2 to C5 alkynylene group, or may be an unsaturated aliphatic hydrocarbon group including at least one or more carbon triple bond.

In an implementation, Chemical Formula 1 may be represented by, e.g., Chemical Formula 1-1 or Chemical Formula 1-2.

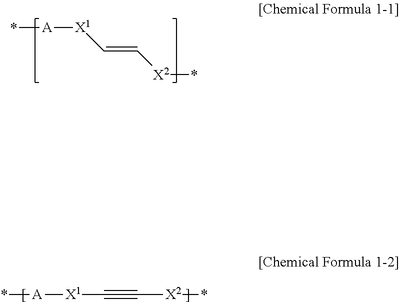

In Chemical Formula 1-1 and Chemical Formula 1-2, A may be, e.g., a substituted or unsubstituted aromatic hydrocarbon group of a moiety Group 1 or a moiety of Group 1-1. X¹ and X² may each independently be, e.g., a single bond, —C(═O)—, a substituted or unsubstituted C1 to C30 alkylene group, or a combination thereof. * is a linking point.

In an implementation, Chemical Formula 1 may be represented by one of, e.g., Chemical Formula 1-1-1 to Chemical Formula 1-1-4 and Chemical Formula 1-2-1 to Chemical Formula 1-2-4.

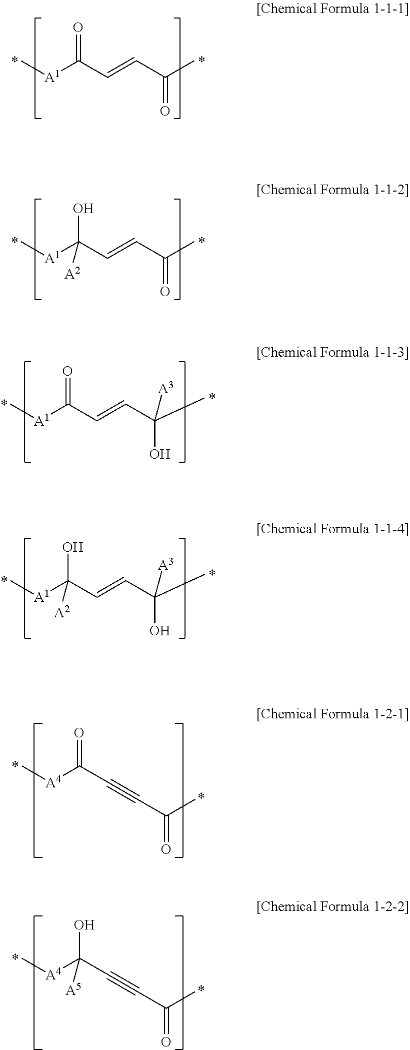

In Chemical Formula 1-1-1 to Chemical Formula 1-1-4 and Chemical Formula 1-2-1 to Chemical Formula 1-2-4, A1 to A6 may each independently be, e.g., a substituted or unsubstituted C6 to C30 aromatic hydrocarbon group, such as a substituted or unsubstituted aromatic hydrocarbon group of a moiety of Group 1 or a moiety of Group 1-1. In an implementation, A1 to A6 may each independently be or include, e.g., a phenyl group, a naphthalene group, a biphenyl group, an anthracene group, a phenanthrene group, a pyrene group, or a benzoperylene group. In an implementation, A¹ to A⁶ may each independently be or include, e.g., a naphthalene group, a biphenyl group, a pyrene group, or a benzoperylene group.

In an implementation, the polymer may further include a structural unit represented by Chemical Formula 2.

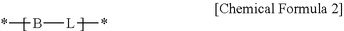

In Chemical Formula 2, B may be or may include, e.g., a substituted or unsubstituted C6 to C30 aromatic hydrocarbon group.

L may be or may include, e.g., a single bond or a substituted or unsubstituted C1 to C30 alkylene group.

* is a linking point.

B in Chemical Formula 2 may be, e.g., a substituted or unsubstituted aromatic hydrocarbon group of a moiety of Group 2.

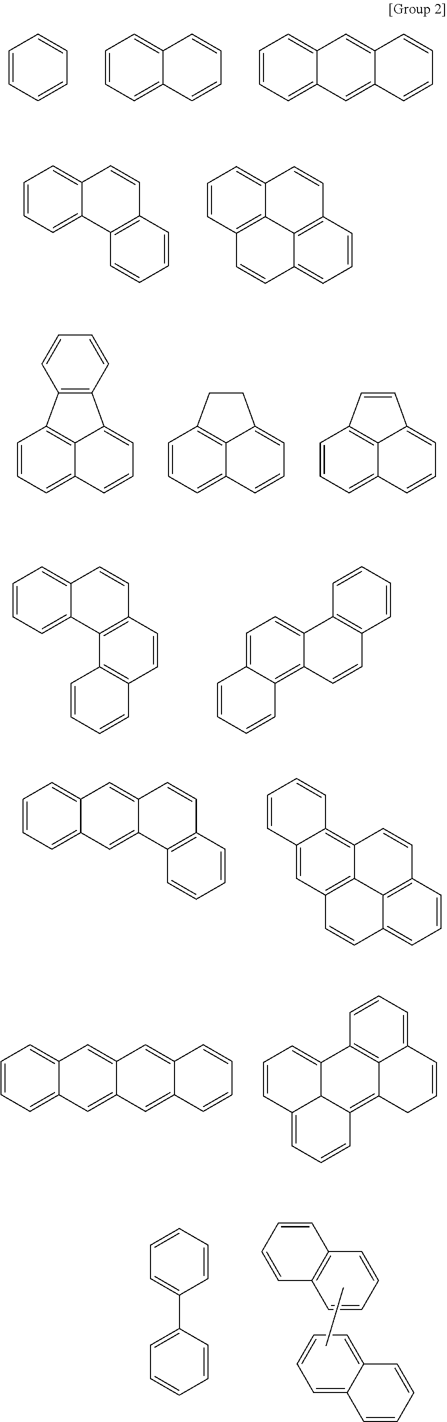

In an implementation, L in Chemical Formula 2 may be, e.g., a substituted or unsubstituted methylene group. In an implementation, L in Chemical Formula 2 may be, e.g., an unsubstituted methylene group.

The polymer may have a weight average molecular weight of about 1,000 g/mol to about 200,000 g/mol. In an implementation, the polymer may have a weight average molecular weight of, e.g., about 1,000 g/mol to about 150,000 g/mol, about 1,000 g/mol to about 100,000 g/mol, about 1,000 g/mol to about 10,000 g/mol, or about 1,200 g/mol to about 5,000 g/mol. By having a weight average molecular weight within the above ranges, the carbon content and solubility in the solvent of the hardmask composition including the above polymer may be adjusted and optimized.

The polymer may be included in an amount of, e.g., about 0.1 wt % to about 30 wt %, based on a total weight of the hardmask composition. In an implementation, the polymer may be included in an amount of, e.g., about 0.2 wt % to about 30 wt %, about 0.5 wt % to about 30 wt %, about 1 wt % to about 30 wt %, about 1 wt % to about 25 wt %, or about 1 wt % to about 20 wt %. By including the polymer within the above ranges, a thickness, a surface roughness, and a planarization degree of the hardmask may be easily adjusted.

The hardmask composition may include a solvent. In an implementation, the solvent may include, e.g., propylene glycol, propylene glycol diacetate, methoxy propanediol, diethylene glycol, diethylene glycol butyl ether, tri (ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. In an implementation, the solvent may be a suitable solvent that has sufficient solubility or dispersibility for the polymer.

In an implementation, the hardmask composition may further include an additive, e.g., a surfactant, a crosslinking agent, a thermal acid generator, or a plasticizer.

The surfactant may include, for example, a fluoroalkyl-based compound, alkylbenzenesulfonate, alkylpyridinium salt, polyethylene glycol, a quaternary ammonium salt, and the like.

The crosslinking agent may be, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

In an implementation, the thermal acid generator may be, e.g., an acid compound, such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid, or 2,4,4,6-tetrabromocyclohexadienone, benzointosylate, 2-nitrobenzyltosylate, or other organic sulfonic acid alkyl esters.

According to some embodiments, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned polymer and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer. The substrate may be, e.g., a silicon wafer, a glass substrate, or a polymer substrate.

The material layer may be a material to be finally patterned, e.g., a metal layer such as an aluminum layer or a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition may be the same as described above, and may be applied by spin-on coating in the form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 1,000° C. for about 10 seconds to about 1 hour, and, e.g., the heat-treating may be performed under an atmosphere of air, nitrogen, or an atmosphere having oxygen concentration of about 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 100° C. to about 400° C. for about 10 seconds to about 1 hour, e.g., about 100° C. to about 1,000° C., for example, about 300° C. to about 1,000° C., about 500° C. to about 1,000° C., or about 500° C. to about 800° C. for about 10 seconds to about 1 hour. In an implementation, the first and second heat-treating may be performed under an atmosphere of air, nitrogen, or an oxygen concentration of about 1 wt % or less.

By performing at least one of the steps of heat-treating the hardmask composition at a high temperature, e.g., of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may include, e.g., SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may be, e.g., N₂/O₂, CHF₃, CF₄, Cl₂, BCl₃, or a mixed gas thereof.

The etched material layer may be formed in a plurality of patterns, and the plurality of patterns may be a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis Examples 1 to 3: Synthesis of Polymers

### Synthesis Example 1

2-hydroxypyrene (15.8 g, 0.05 mol), 1,1′-biphenyl-4-ol (8.5 g, 0.05 mol), and dimethyl fumaric acid (14.4 g, 0.1 mol) were put in a 250 ml flask. Subsequently, p-toluene sulfonic acid monohydrate (0.57 g, 0.03 mmol) was dissolved in 100 g of propylene glycol monomethyl ether acetate (PGMEA), and this solution was added to the flask and then, stirred at 100° C. After taking a sample from the polymerization reactant at one hour intervals, when the sample had a weight average molecular weight of 2,000 to 2,500 g/mol, a reaction was completed. When the polymerization reaction was completed, the reactant was cooled to ambient temperature and added to 300 g of distilled water and 300 g of methanol and then, vigorously stirred and allowed to stand. After removing a supernatant therefrom, precipitates therefrom were dissolved in 100 g of PGMEA and then, stirred in 300 g of methanol and 300 g of distilled water and allowed to stand (primary process). Herein, after removing a supernatant obtained therefrom again, precipitates therefrom were dissolved in 80 g of PGMEA (secondary process). The primary process and the secondary process were regarded as one purification process, which was performed three times in total. After the purification, a polymer therefrom was dissolved in 80 g of (PGMEA, and methanol and distilled water remaining in the solution was removed under a reduced pressure to obtain a polymer including structural units represented by Chemical Formulae 1-1-1 to 1-1-4. In Chemical Formulae 1-1-1 to 1-1-4, A¹ to A³ are each independently moieties derived from 2-hydroxypyrene or 1,1′-biphenyl-4-ol.

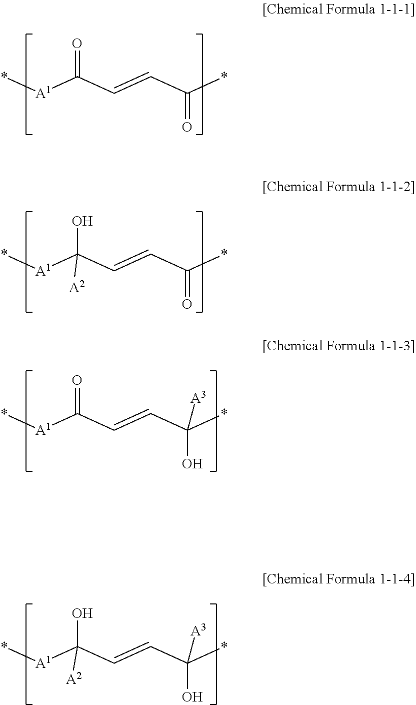

### Synthesis Example 2

A polymer including structural units represented by Chemical Formulae 1-2-1 to 1-2-5 was prepared in the same method as in Synthesis Example 1 except that 2,2′-biphenol (18.6 g, 0.1 mol), dimethyl acetylene dicarboxylate, (14.2 g, 0.05 mol), and paraformaldehyde (1.5 g, 0.05 mol) were used as a reactant. In Chemical Formulae 1-2-1 to 1-2-5, A⁴ to A⁷ are each independently moieties derived from the 2,2′-biphenol.

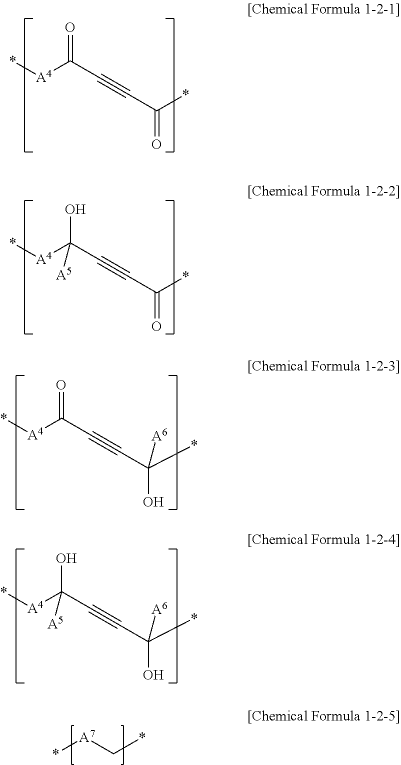

### Synthesis Example 3

A polymer including structural units represented by Chemical Formulae 1-3-1 to 1-3-5 was prepared in the same method as in Synthesis Example 1 except that 2-hydroxypyrene (15.8 g, 0.05 mol), 2,2′-biphenol (18.6 g, 0.1 mol), fumaric acid (11.6 g, 0.1 mol), and paraformaldehyde (1.5 g, 0.05 mol) were used as a reactant. In Chemical Formulas 1-3-1 to 1-3-5, A⁸ to A¹¹ are each independently moieties derived from 2-hydroxypyrene or 2,2′-biphenol.

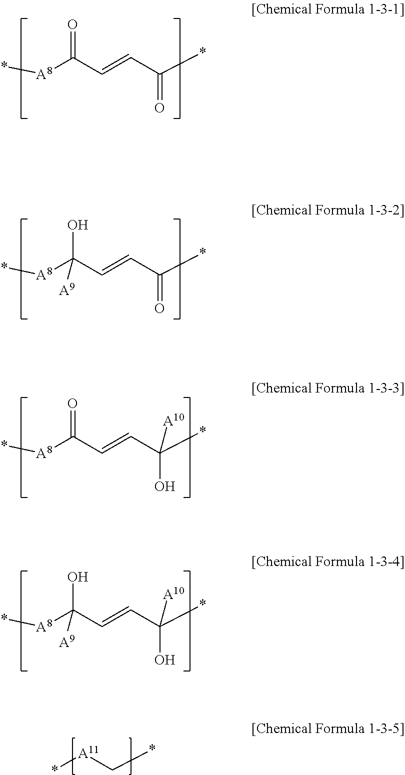

### Synthesis Example 4

Naphthalen-1-ol (14.4 g, 0.1 mol) and dimethyl fumarate (14.4 g, 0.1 mol) were put in a 250 ml flask. Subsequently, p-toluene sulfonic acid monohydrate (0.57 g, 0.03 mmol) was dissolved in 100 g of PGMEA, and this solution was added to the flask and then, stirred at 100° C. After taking a sample from the polymerization reactant at one hour intervals, when the sample had a weight average molecular weight of 2,000 to 2,500 g/mol, a reaction was completed. When the polymerization reaction was completed, the reactant was cooled to ambient temperature and added to 300 g of distilled water and 300 g of methanol and then, vigorously stirred and allowed to stand. After removing a supernatant therefrom, precipitates therefrom were dissolved in 100 g of PGMEA and then, stirred by using 300 g of distilled water and 300 g of methanol and then, vigorously stirred and allowed to stand (primary process). Herein, after removing a supernatant obtained therefrom again, precipitates therefrom were dissolved in 80 g of PGMEA (secondary process). The primary process and the secondary process were regarded as one purification process, which was performed three times in total. After the purification, a polymer therefrom was dissolved in 80 g of PGMEA, and methanol and distilled water remaining in the solution was removed under a reduced pressure to obtain a polymer including structural units represented by Chemical Formulae 1-4-1 to 1-4-4. In Chemical Formulae 1-4-1 to 1-4-4, A¹² to A¹⁵ are each independently a moiety derived from 1-naphthol.

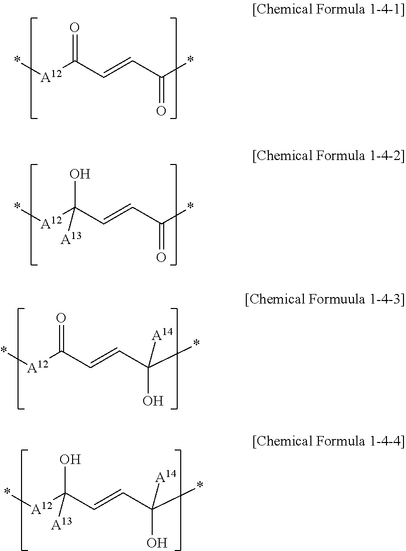

### Comparative Synthesis Example 1

Pyrene (20.2 g, 0.1 mol) and 4-hydroxybenzaldehyde (12.2 g, 0.1 mol) were put in a 250 ml flask. Subsequently, p-toluene sulfonic acid monohydrate (0.57 g, 0.03 mmol) was dissolved in 100 g of PGMEA, and this solution was added to the flask and then, stirred at 100° C. After taking sample from the polymerization reactant at one hour intervals, a reaction was completed, when a weight average molecular weight thereof reached 2,000 to 2,500 g/mol. When the polymerization reaction was completed, the reactant was cooled to ambient temperature and added to 300 g of distilled water and 300 g of methanol and then, vigorously stirred and allowed to stand. After removing a supernatant therefrom, precipitates therefrom were dissolved in 100 g of PGMEA and then, stirred by using 300 g of methanol and 300 g of distilled water and then, allowed to stand (primary process). Herein, after removing a supernatant obtained therefrom again, precipitates therefrom were dissolved in 80 g of PGMEA (secondary process). The primary process and the secondary process were regarded as one purification process, which was performed three times in total. After the purification, a polymer therefrom was dissolved in 80 g of PGMEA, and methanol and distilled water remaining in the solution was removed under a reduced pressure to obtain a polymer including a structural unit represented by Chemical Formula P.

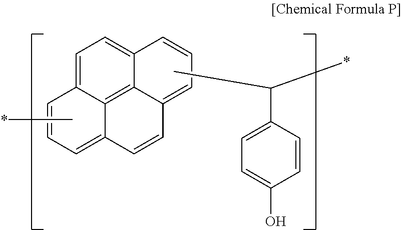

### Comparative Synthesis Example 2

A polymer including a structural unit represented by Chemical Formula Q was prepared in the same method as in Comparative Synthesis Example 1 except that 2-hydroxypyrene (21.8 g, 0.1 mol) instead of the pyrene and 4-naphthanlealdehyde (15.6 g, 0.1 mol) instead of the hydroxybenzaldehyde were used.

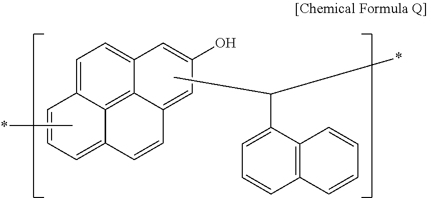

### Comparative Synthesis Example 3

In a 500 ml two-necked flask equipped with a mechanical agitator and a cooling tube, methoxypyrene (40 g, 0.172 mol) and terephthaloyl chloride (17.48 g, 0.086 mol) were added to 300 g of 1,2-dichloroethane) and then, well stirred. After 15 minutes, trichloro aluminum (25.26 g, 0.189 mol) was slowly added thereto, and then, the reaction solution was reacted at ambient temperature for 5 hours. When the reaction was completed, after removing the trichloro aluminum by using water, the residue was concentrated with an evaporator. Subsequently, 1-dodecanethiol (41.78 g, 0.21 mol), potassium hydroxide (15.46 g, 0.27 mol), and N,N-dimethyl formamide (230 g) were added to the obtained compound (40.96 g, 0.068 mol) in the flask and then, stirred at 120° C. for 8 hours. Subsequently, the mixture was cooled and neutralized into pH 7 by using a 5% hydrogen chloride solution and then, extracted with ethyl acetate and dried. Then, tetrahydrofuran (160 g) was added to the obtained compound to obtain a solution. To this solution, a sodium borohydride (32 g, 0.84 mol) aqueous solution was slowly added and then, stirred at ambient temperature for 12 hours. When a reaction was completed, the resultant was acidified to pH 5 with a 7% hydrogen chloride solution and extracted with ethyl acetate, and an organic solvent was treated under a reduced pressure. This synthesized polymer (10 g, 0.017 mol), bis(triphenylphosphine) palladium (II) dichloride (Pd(PPh₃)₂Cl₂, 0.6 g, 0.0008 mol), copper iodide (0.16 g, 0.0008 mol), triphenylphosphine (0.44 g, 0.0016 mol), and triethylamine (36 mL) were dissolved in 60 mL of tetrahydrofuran. Subsequently, 3.5 g of ethynyltrimethylsilane was added thereto and then, stirred at 80° C. for 3 hours. When a reaction was completed, the resultant was purified by filtration using silica gel. 12.5 g (1 equivalent) of the purified solid was dissolved in 250 ml of an MeOH/THE solution (in a volume ratio=1/2), and 20 g of potassium carbonate (7 equivalent) was added thereto and then, stirred at ambient temperature for 6 hours. When a reaction was completed, the resultant was extracted with ethyl acetate and treated under a reduced pressure to obtain a compound represented by Chemical Formula R.

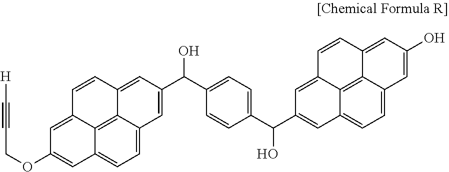 [SMILES: C#CCOc1cc2ccc3cc(C(O)c4ccc(C(O)c5cc6ccc7cc(O)cc8ccc(c5)c6c78)cc4)cc4ccc(c1)c2c34]

### Preparation of Hardmask Composition

### EXAMPLE 1

3 g of the polymer according to Synthesis Example 1 was dissolved in 10 g of PGMEA and then, filtered with a 0.1 μm TEFLON (tetrafluoroethylene) filter to prepare a hardmask composition.

### EXAMPLE 2

A hardmask composition was prepared in the same method as Example 1 except that the polymer of Synthesis Example 2 was used instead of the polymer of Synthesis Example 1.

### EXAMPLE 3

A hardmask composition was prepared in the same method as Example 1 except that the polymer of Synthesis Example 3 was used instead of the polymer of Synthesis Example 1.

### EXAMPLE 4

A hardmask composition was prepared in the same method as Example 1 except that the polymer of Synthesis Example 4 was used instead of the polymer of Synthesis Example 1.

### COMPARATIVE EXAMPLE 1

A hardmask composition was prepared in the same method as Example 1 except that the polymer of Comparative Synthesis Example 1 was used instead of the polymer of Synthesis Example 1.

### COMPARATIVE EXAMPLE 2

A hardmask composition was prepared in the same method as Example 1 except that the polymer of Comparative Synthesis Example 2 was used instead of the polymer of Synthesis Example 1.

### COMPARATIVE EXAMPLE 3

A hardmask composition was prepared in the same method as Example 1 except that the polymer of Comparative Synthesis Example 3 was used instead of the polymer of Synthesis Example 1.

### Evaluation 1: Evaluation of Film Strength

Each of the hardmask compositions of Examples 1 to 4 and Comparative Examples 1 to 3 was spin-on coated to be 5,000 Å thick on a silicon wafer and then, heat-treated on a hot plate at 400° C. for 2 minutes to form a thin film. Subsequently, the thin film was measured with respect to hardness (H) and a modulus (E) by using Nanoindenter (cube corner tip, Pmax=300 μN). The measurement results are shown in Table 1.

TABLE 1

| | Hardness (H, GPa) | Modulus (E, GPa) |
|---|---|---|
| Example 1 | 7.5 | 6.3 |
| Example 2 | 6.9 | 6.8 |
| Example 3 | 8.0 | 6.9 |
| Example 4 | 7.1 | 6.5 |
| Comparative Example 1 | 4.3 | 4.2 |
| Comparative Example 2 | 4.1 | 4.7 |
| Comparative Example 3 | 4.5 | 4.1 |

Referring to Table 1, hard masks of the hardmask compositions according to Examples 1 to 4 exhibited much higher hardness and modulus, compared with hard masks formed of the hardmask compositions according to Comparative Examples 1 to 3. The hard masks formed of the hardmask compositions according to the Examples exhibited excellent film hardness and excellent mechanical properties, compared with those of the hardmask compositions according to the Comparative Examples.

### Evaluation 2: Evaluation of Pattern-forming Ability

A 3,000 Å-thick silicon oxide (SiOx) layer was formed on a silicon wafer in a chemical vapor deposition (CVD) method. Subsequently, each of the hardmask compositions according to Examples 1 to 4 and Comparative Examples 1 to 3 was coated on the silicon oxide layer in a spin coating method and then, heat-treated at 350° C. for 120 seconds to form a hardmask layer. Subsequently, on the hardmask layer, a silicon nitride (SiNx) layer was formed in the chemical vapor deposition (CVD) method. Subsequently, a photoresist for KrF was spin-coated and then, heat-treated at 110° C. for 60 seconds, exposed to light with an ASML (XT: 1400, NA 0.93) exposer, and developed in a tetramethylammonium hydroxide (TMAH, 2.38 wt %) aqueous solution. Then, the photoresist patterned through the process was used as a mask, and CHF₃/CF₄ mixed gas plasma was also used to dry-etch the silicon nitride (SiNx) layer. Subsequently, the silicon nitride (SiNx) layer patterned through the process was used as a mask, and N₂/O₂ mixed gas plasma also was used to dry-etch the hardmask layers according to Examples 1 to 4 and Comparative Examples 1 to 3. An electron scanning microscope (SEM) was used to examine the cross-section of the hardmask pattern. The hardmask layers formed of the compositions according to the Comparative Examples exhibited pattern collapse, but the hardmask layers formed of the compositions according to the Examples exhibited a good vertical shape and thus excellent pattern-forming ability.

Accordingly, the hard masks formed of the hardmask composition according to some embodiments exhibited excellent coating properties in a solution state and thus excellent smoothness and pattern-forming ability as well as excellent hardness and modulus and thus excellent mechanical properties such as film strength.

By way of summation and review, there is a constant trend in a semiconductor industry to reduce a size of chips. To respond to this, the line width of the resist patterned in lithography technology may have a size of several tens of nanometers. Therefore, a height that can withstand the line width of the resist pattern may be limited, and there are cases where the resists may not have sufficient resistance in the etching step. In order to compensate for this, an auxiliary layer, which is called a hardmask layer, may be used between a material layer to be etched and a photoresist layer. This hardmask layer may serve as an interlayer that transfers a fine pattern of the photoresist through selective etching and thus, the hardmask layer may have etch resistance and crosslinking characteristics to withstand the etching process required for pattern transfer.

Some hardmask layers may be formed in a chemical or physical deposition method and may have low economic efficiency due to a large-scale equipment and a high process cost. Accordingly, a spin-coating technique for forming a hardmask layer has recently been developed. The spin-coating technique may be an easier process to conduct than some other methods, and a hardmask layer formed therefrom may exhibit much more excellent gap-fill characteristics and planarization characteristics, and the etch resistance for the hardmask layer may tend to decrease somewhat.

A hardmask composition may be applied by the spin-coating technique and may help secure equivalent etch resistance to that of the hardmask layer formed in the chemical or physical deposit method. In order to improve the etch resistance of a hardmask layer, research on maximizing a carbon content of the hardmask composition is being actively made.

One or more embodiments may provide a hardmask composition that can form a hardmask without deteriorating etch resistance while applying a spin-coating technique. A composition for forming a hardmask, in which etch resistance of the hardmask layer can be improved by increasing the carbon content in the polymer, crosslinking characteristics are improved by including a functional group containing a heteroatom and an unsaturated hydrocarbon group in the polymer, and mechanical properties of the hardmask layer produced therefrom are improved, may be provided.

One or more embodiments may provide a hardmask composition that can be effectively applied to a hardmask layer.

The hardmask composition according to some embodiments may have excellent crosslinking characteristics, and the hardmask layer formed therefrom may help secure excellent mechanical properties and pattern-forming ability.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a polymer including a structural unit represented by Chemical Formula 1; and
a solvent: 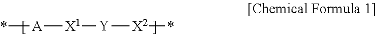
wherein, in Chemical Formula 1,
A is a substituted or unsubstituted C6 to C30 aromatic hydrocarbon group,
X¹ and X² are each independently a single bond, —C(═O)—, a substituted or unsubstituted C1 to C30 alkylene group, or a combination thereof,
Y is a substituted or unsubstituted C2 to C30 alkenylene group or a substituted or unsubstituted C2 to C30 alkynylene group, and
is a linking point.

2. The hardmask composition as claimed in claim 1, wherein A is a substituted or unsubstituted C6 to C30 aromatic hydrocarbon group of a moiety of Group 1:

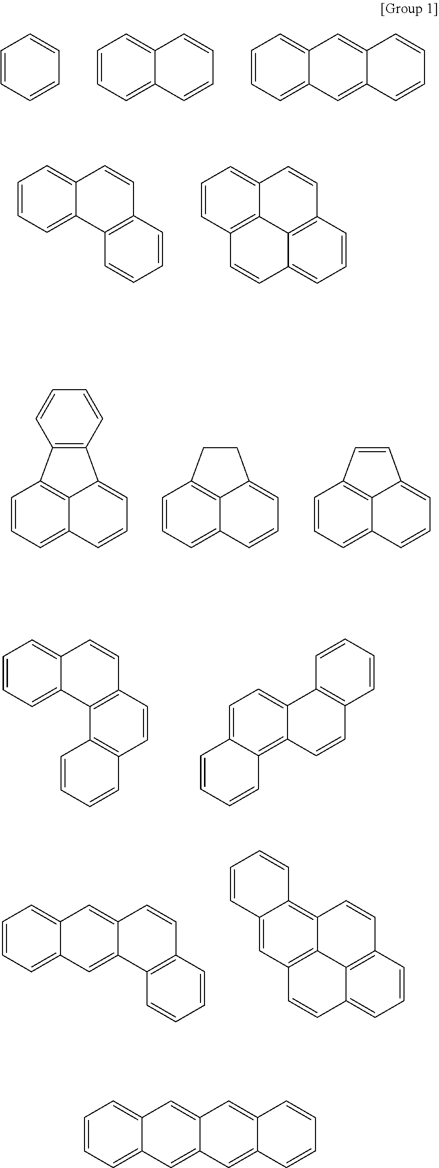

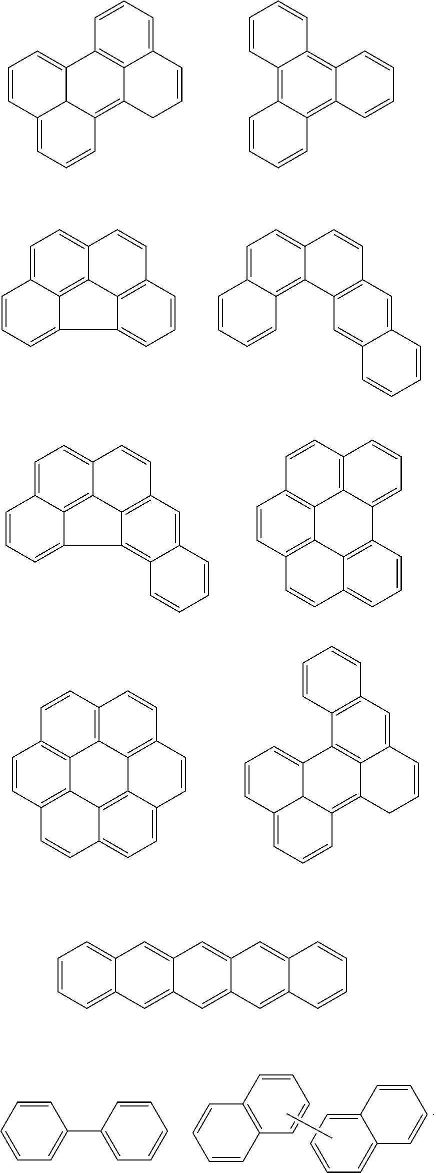

3. The hardmask composition as claimed in claim 2, wherein:
A is a substituted C6 to C30 aromatic hydrocarbon group, and
a substituent of the substituted C6 to C30 aromatic hydrocarbon group is deuterium, a hydroxy group, a halogen atom, a C1 to C20 alkyl group, a C2 to C20 alkenyl group, a C2 to C20 alkynyl group, a C1 to C20 heteroalkyl group, a C6 to C20 aryl group, a C3 to C20 heteroaryl group, or a combination thereof.

4. The hardmask composition as claimed in claim 1, wherein X¹ and X² are each independently —C(═O)—, a substituted C1 to C20 alkylene group, or a combination thereof.

5. The hardmask composition as claimed in claim 1, wherein Y is a substituted or unsubstituted C2 to C10 alkenylene group or a substituted or unsubstituted C2 to C10 alkynylene group.

6. The hardmask composition as claimed in claim 1, wherein A is a substituted or unsubstituted C6 to C30 aromatic hydrocarbon group of a moiety of Group 1-1:

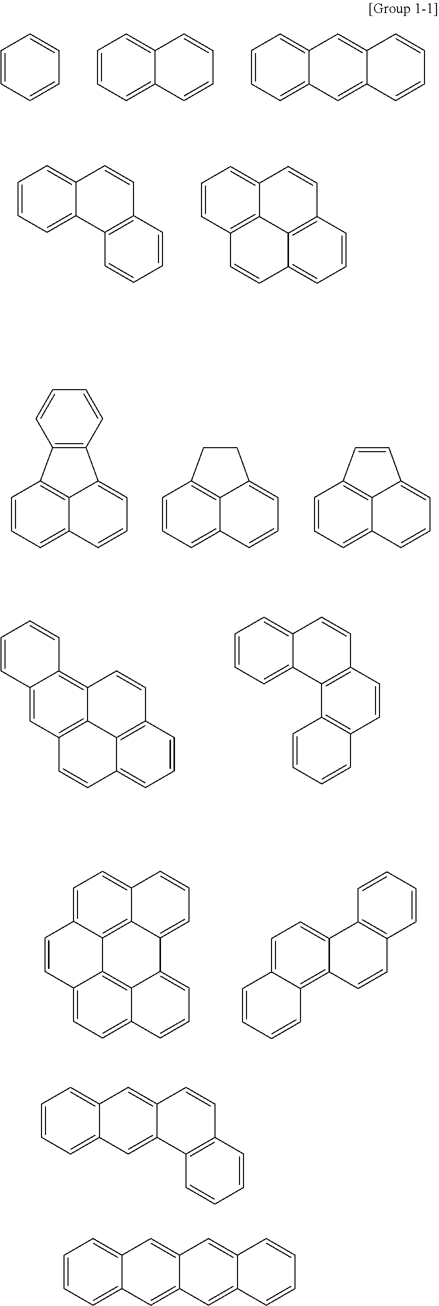

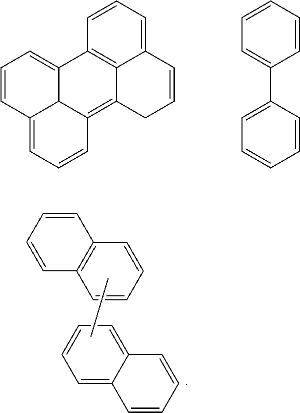

7. The hardmask composition as claimed in claim 1, wherein:
Chemical Formula 1 is represented by Chemical Formula 1-1 or Chemical Formula 1-2: 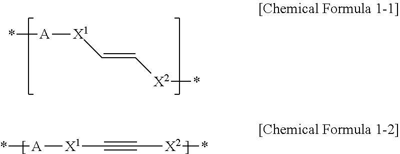
in Chemical Formula 1-1 and Chemical Formula 1-2,
A is a substituted or unsubstituted C6 to C30 aromatic hydrocarbon group of a moiety of Group 1-1,
X¹ and X² are each independently a single bond, —C(═O)—, a substituted or unsubstituted CI to C30 alkylene group, or a combination thereof, and
is a linking point:

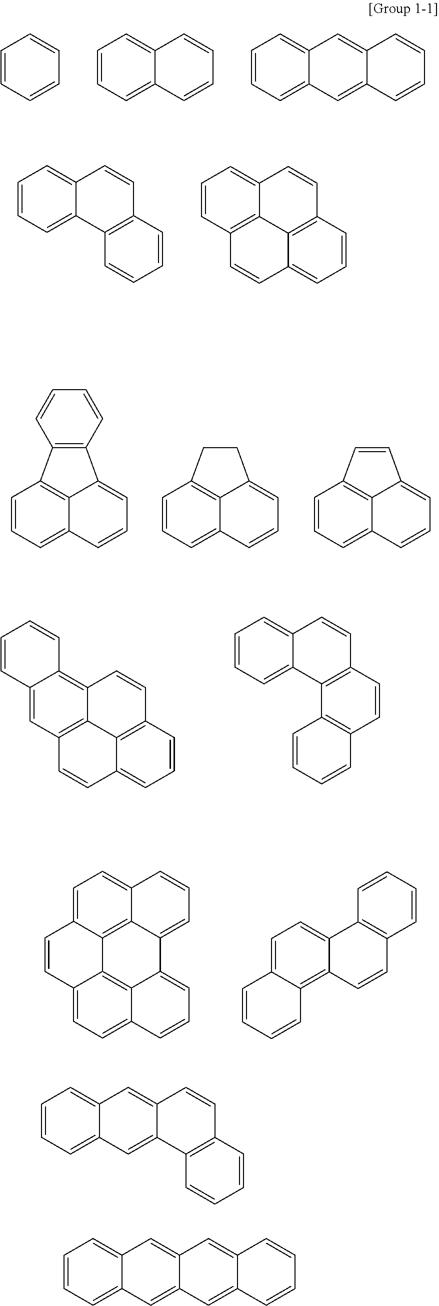

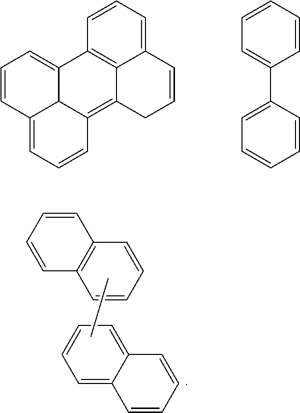

8. The hardmask composition as claimed in claim 1, wherein:
Chemical Formula 1 is represented by one of Chemical Formula 1-1-1 to Chemical Formula 1-1-4 and Chemical Formula 1-2-1 to Chemical Formula 1-2-4: 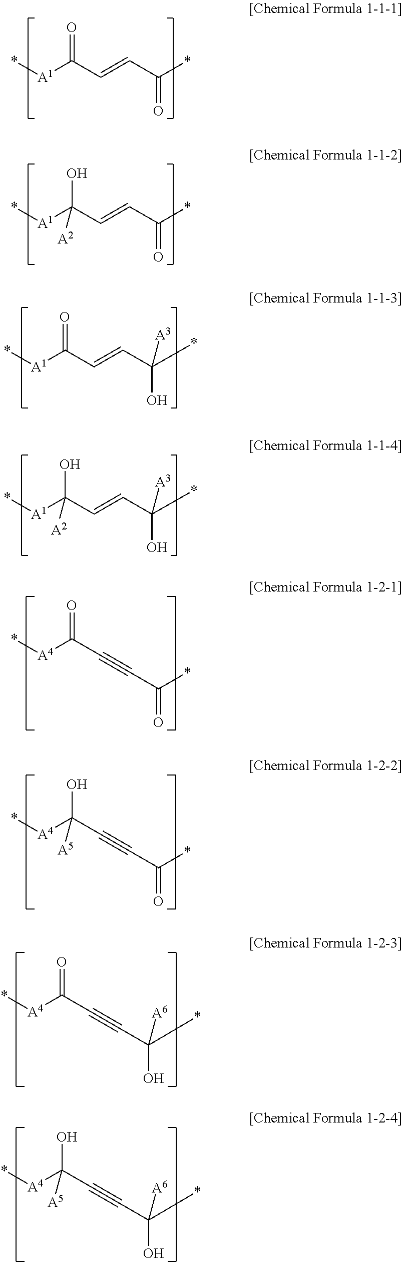
in Chemical Formula 1-1-1 to Chemical Formula 1-1-4 and Chemical Formula 1-2-1 to Chemical Formula 1-2-4, A¹ to A⁶ are each independently a substituted or unsubstituted C6 to C30 aromatic hydrocarbon group.

9. The hardmask composition as claimed in claim 8, wherein A¹ to A⁶ are each independently a substituted or unsubstituted C6 to C30 aromatic hydrocarbon group of a moiety of Group 1-1:

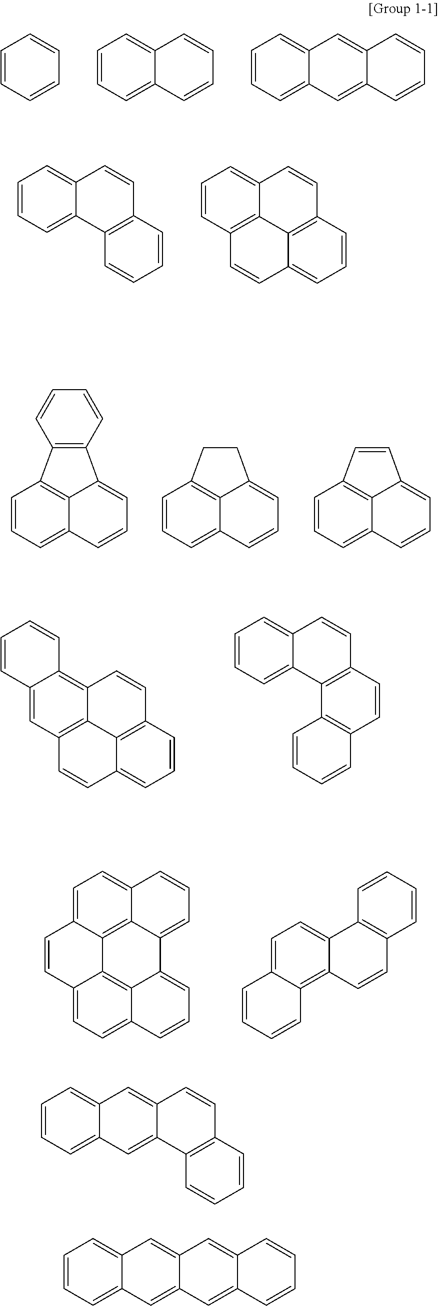

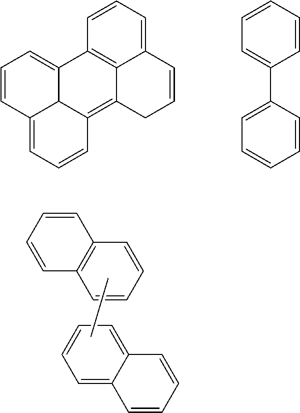

10. The hardmask composition as claimed in claim 1, wherein:
the polymer further includes a structural unit represented by Chemical Formula 2, 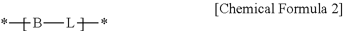
in Chemical Formula 2,
B is a substituted or unsubstituted C6 to C30 aromatic hydrocarbon group,
L is a single bond or a substituted or unsubstituted C1 to C30 alkylene group, and
is a linking point.

11. The hardmask composition as claimed in claim 10, wherein B in Chemical Formula 2 is a substituted or unsubstituted C6 to C30 aromatic hydrocarbon group of a moiety of Group 2:

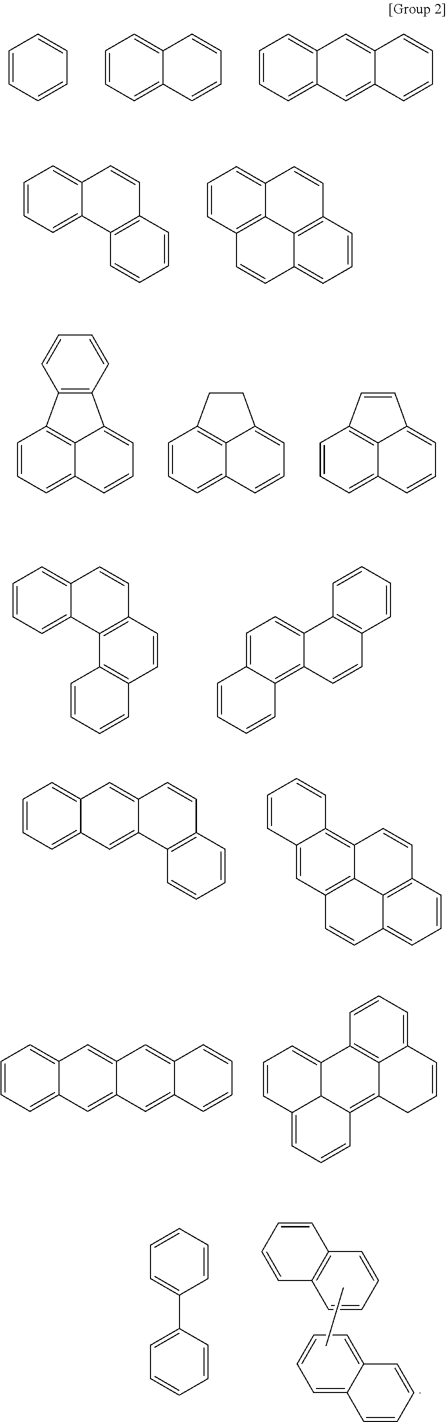

12. The hardmask composition as claimed in claim 10, wherein L in Chemical Formula 2 is a substituted or unsubstituted methylene group.

13. The hardmask composition as claimed in claim 1, wherein the polymer has a weight average molecular weight of about 1,000 g/mol to about 200,000 g/mol.

14. The hardmask composition as claimed in claim 1, wherein the polymer is included in an amount of about 0.1 wt % to about 30 wt %, based on a total weight of the hardmask composition.

15. The hardmask composition as claimed in claim 1, wherein the solvent includes propylene glycol, propylene glycol diacetate, methoxy propanediol, diethylene glycol, diethylene glycol butylether, tri (ethylene glycol) monomethylether, propylene glycol monomethylether, propylene glycol monomethylether acetate, cyclohexanone, ethyl lactate, gamma-butyrolactone, N,N-dimethyl formamide, N,N-dimethyl acetamide, methylpyrrolidone, methylpyrrolidinone, acetylacetone, or ethyl 3-ethoxypropionate.

16. A hardmask layer comprising a cured product of the hardmask composition as claimed in claim 1.

17. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

18. The method as claimed in claim 17, wherein forming the hardmask layer includes heat-treating at about 100° C. to about 1,000° C.
